(19) United States
(12) Patent Application Publication
(10) Pub. No.: US 2020/0159122 A1
(43) Pub. Date: May 21, 2020

(54) METHOD AND APPARATUS FOR IMMERSION GRATING LITHOGRAPHY

(71) Applicant: Newport Corporation, Irvine, CA (US)

(72) Inventors: Svetlen H. Tonchev, Fairport, NY (US); Dilyana S. Mihalova, Rochester, NY (US); Jason E. Rama, Victor, NY (US)

(73) Assignee: Newport Corporation, Irvine, CA (US)

(21) Appl. No.: 16/672,237

(22) Filed: Nov. 1, 2019

Related U.S. Application Data
(60) Provisional application No. 62/770,340, filed on Nov. 21, 2018.

(51) Int. Cl. G03F 7/20; G02B 5/18; H01L 21/027

(52) U.S. Cl. CPC G03F 7/2041; G02B 5/1838; G02B 5/1814; G03F 7/70883; H01L 21/0275; G03F 7/2006; G03F 7/702; G02B 5/1847

(57) ABSTRACT

The present application is directed to an improved immersion grating assembly that provides additional wavelength dispersion and higher optical efficiency at ultraviolet wavelengths relative to prior art devices. More specifically, the immersion grating disclosed herein may be used to narrow the spectrum of light emitted by excimer laser systems. Narrower spectral linewidth of excimer laser systems may enable the creation of smaller feature sizes in semiconductor structures manufactured using UV photolithography processes.

### CROSS-REFERENCE TO RELATED APPLICATIONS

The present application claims priority to U.S. Provisional Patent Application Ser. No. 62/770,340—entitled “Method and Apparatus for Immersion Grating Lithography”, filed on Nov. 21, 2018, the contents of which are incorporated by reference in their entirety herein.

### BACKGROUND

Modern semiconductor manufacturing methods continue to improve the performance of integrated circuits used in a variety of applications such as computers, cell phones, tablets and data storage devices. Integrated circuits are evolving to operate faster and use less power than their predecessors. A key enabler of these features is the increase in semiconductor component density and the decrease in the feature size of the semiconducting structures written in silicon wafers using photolithography. Photolithography processes require high power illumination sources operating at shorter wavelengths, extending well into the UV portion of the electromagnetic spectrum. Additionally, these illumination sources must be efficient and provide UV light with narrow spectral linewidth.

Diffractive and dispersive optics are used in photolithography applications to narrow the spectral linewidth of certain light sources, including excimer lasers that operate in the wavelength range between 100 nanometers (nm) and 400 nm. Highly dispersive optical gratings such as echelle gratings are well suited to such linewidth-narrowing applications. FIG. 1 shows a prior art echelle grating in air having a nominal index of refraction n=1, also referred to hereinafter as a “bare” grating. Such echelle gratings are often configured with a “blaze angle” θ_{B} that is the angle between the face of the groove and the plane of the grating as shown in FIG. 1. When the angle of incidence α is equal to the diffraction angle β, the grating is considered to have a “Littrow blaze condition”, where the grating acts as a reflective mirror at a defined blaze wavelength and the grating is said to be “blazed” at a particular wavelength.

Gratings configured in a Littrow blaze condition can be used as a high-reflective dispersing mirror as part of a laser cavity. For example, a prior art grating in a Littrow configuration shown in FIG. 1 may disperse an incoming light beam generated by a laser gain medium that has a spectral linewidth of Δλₙ into discrete wavelengths λ₁, λ₂ and λ₃, with the light at wavelengths λ₂ and λ₃ being diffracted at angles γ₁ and γ₂ respectively. The light with a wavelength λ₁ is diffracted or reflected back in the same direction as the incoming light. FIGS. 2A and 2B shows simplified schematics of lasers with or without a line narrowing module. As shown, the light at wavelengths λ₂ and λ₃ is blocked by an aperture and only the light at wavelength λ₁ reaches the laser gain medium to be amplified and emitted as light with a spectral linewidth of Δλ₁₀₀ that is narrower than the spectral linewidth Δλₙ of the light originally generated by the laser gain medium. Even if no aperture is used, dispersed light with wavelengths λ₂ and λ₃ may couple into non-resonating modes in the laser gain medium. FIGS. 3A and 3B shows examples of the spectral linewidths centered at λ₁ emitted by a laser without a line-narrowing module and a laser with a line-narrowing module. The spectral linewidth Δλ may be defined as the width of the intensity distribution by wavelength measured at half the maximum intensity, known as the full-width half maximum (FHWM) measurement. For example, a laser without a line-narrowing module may have an output beam with the spectral linewidth Δλₙ of about 2.8 picometers (pm). The same laser used with a line-narrowing module may emit an output beam with a narrower spectral linewidth Δλ₁₀₀ of about 2.0 pm. When used in the typical photolithography apparatus 10, the narrowed linewidth Δλ₁₀₀ of an excimer laser may help to increase the resolution of the apparatus, enabling it to write smaller features in semiconductor wafers.

One approach to improving the linewidth-narrowing performance of gratings is to increase the dispersion imparted to the light. The dispersion of some optical gratings can be increased by burying or immersing the diffractive surface of the grating in a prism with an index of refraction n₂ wherein the index of refraction n₂ is higher than the index of refraction of air and with high transmission at the used spectral range. Generally, the light dispersed by an immersed grating has a spectral linewidth that is narrower by the about inverse of the refractive index n₂ (relative to n=1 in air). This type of grating is referred to in the art as an “immersion grating”, “immersed grating”, “embedded grating” or “buried grating”.

FIGS. 4 and 5 show various views of a prior art immersion grating 100. The diffractive surface of the grating 102 is optically coupled and mechanically coupled to a prism 106 with an immersion medium 104, generally an epoxy adhesive. The immersion medium 104 may act as an optical coupling agent between the prism 106 and the grating 102 and can help increase the dispersion imparted by the grating due to the higher index of refraction of the immersion medium 104 relative to air. As shown in FIG. 5, during use, a light beam with a spectral linewidth Δλₙ centered at wavelength λ₁ is directed to the immersion grating 100. The immersion grating 100 imparts angular dispersion to the light beam, leaving a portion of the light beam with wavelength λ₁ diffracted or reflected back substantially opposite to and parallel to the same direction the incident light beam came from. Light beams with wavelengths λ₂ and λ₃ are diffracted from the immersed grating diffractive surface at angles γ₃ and γ₄ respectively relative to the direction of the light of wavelength λ₁. The light beams with wavelengths λ₂ and λ₃ may also be refracted per Snell's law as they exit the prism. As described above in relation to FIG. 1, the bare grating diffracts the incoming light beam at angles γ₁ and γ₂. The diffraction angles γ₃ and γ₄ imparted by the immersion grating are greater than the diffraction angles γ₁ and γ₂ imparted by the bare grating. As such, the prior art immersion grating 100 is capable of providing higher angular dispersion than the bare grating shown in FIG. 1. However, immersion gratings that utilize epoxy adhesives have shortcomings when used at wavelengths below 300 nm. For example, an epoxy adhesive used as an immersion medium may decrease the grating efficiency by as much as a factor of more than four as shown in FIG. 8.

Alternatively, a diffractive surface may be applied to or etched into the surface of a prism. FIG. 6 shows a prior art immersed grating 130 known in the art that is fabricated by replicating a grating structure 134 with a grating surface 135 using an epoxy replication process. The surface 135 is then coated with metal layer 136 so that it reflects incoming light. This method is limited to gratings that operate above 300 nm because epoxy polymer materials typically absorb light at wavelengths less than 300 nm as mentioned above. FIG. 8 shows a graph of simulated grating efficiency relative to wavelength. As shown, a grating in air may have a peak simulated efficiency η of around 70% at 193.0 nm and a grating that is epoxy-replicated onto the prism surface may have a simulated efficiency η of around 15% at 193.0 nm.

FIG. 7 shows a prior art grating 140 with a prism body 142 and grating diffractive surface 144 that may be directly etched or ruled into the surface of the prism body 144. The grating diffractive surface 144 may be coated with metal 146 so that it reflects incoming light. This type of grating can be very expense to manufacture, and there are physical limitations to the grating size, groove frequencies and groove profiles that can be etched or ruled as well as limits to the material the grating structure is etched into.

As described above, while prior art immersion gratings have proven useful in the past, some shortcomings have been identified. For example, materials used in some immersion gratings known in the art may absorb light in the UV part of the optical spectrum, especially below 300 nm, and may thus decrease the optical efficiency of the immersion grating in that wavelength range. Other types of immersion gratings may be prohibitively expensive and difficult to manufacture.

In light of the foregoing, there is an ongoing need for an immersion grating that provides high dispersion and that can be used to narrow the spectral linewidth of lasers at wavelengths below 300 nm without sacrificing optical efficiency.

### SUMMARY

The present application is directed to various embodiments and uses of an improved optical immersion grating assembly configured to provide enhanced or increased optical dispersion. More specifically, the immersion grating assembly may be used to narrow the spectrum of light emitted by laser systems with high optical efficiency in wavelengths below 300 nm. In one embodiment, the present application is directed to an optical grating with at least one grating structure, at least one grating diffractive surface, with the grating positioned in a Littrow or near-Littrow configuration. The immersion grating described herein may be configured to provide optical dispersion to ultraviolet light and may further include at least one prism formed from at least one UV-transmitting material with a first index of refraction and at least one first prism surface and at least one second prism surface. At least one immersion medium with a second index of refraction may be disposed between the grating diffractive surface and the second prism surface, wherein the first index of refraction of the prism and the second index of refraction of the immersion medium are substantially equal and wherein the immersion medium is substantially transmissive at wavelength less than 300 nm. At least one bonding agent may be used to bond the prism, grating and the immersion medium together within at least one retaining structure that may be configured to prevent the immersion medium from absorbing contamination and moisture. Optionally, the immersion medium may be substantially transmissive at wavelengths between about 300 nanometers and about 450 nanometers. In one embodiment, the immersion medium is a fluid such as a glycerol-water mixture. In another embodiment, the immersion medium is an adhesive. In another embodiment, the immersion medium is a viscous pre-form. In an alternate embodiment, the first index of refraction of the prism and the second index of refraction of the immersion medium are not substantially equal.

The present application also discloses various embodiments of a method of manufacturing an immersion grating assembly for use with a laser system. In one embodiment, the method of manufacture comprises selecting an optical grating to be immersed, the optical grating including at least one grating structure, at least one grating diffractive surface, and configured to be positioned in a Littrow or near-Littrow configuration. The method further comprises selecting at least one prism formed from a UV-transmitting material with a first index of refraction and at least one first prism surface and at least one second prism surface. The method further comprises optically contacting the grating diffractive surface to the second surface of the prism with at least one immersion medium having a second index of refraction, such that reflections between the second surface of the prism and the grating diffractive surface are minimized. The method further comprises installing the grating and immersion medium in at least one retaining structure and bonding the prism to at least one surface of the retaining structure to prevent the immersion medium from absorbing contamination and moisture.

The present application also discloses a method of line-narrowing an excimer laser, wherein at least one immersion grating assembly is placed in optical communication with at least one excimer laser gain medium wherein the immersion grating assembly is configured to provide angular dispersion to at least one first light beam with a first central wavelength and a first spectral linewidth. During use, the first light beam is directed to the immersion grating assembly, thereby dispersing the first light beam into multiple wavelength components. At least one aperture blocks light with wavelengths other than the central wavelength from propagating back to the excimer laser gain medium. A second light beam with the first central wavelength is diffracted or reflected back into the excimer laser gain medium and is amplified and emitted by the excimer laser.

Further, the present application is directed to a method of excimer laser lithography wherein at least one excimer laser is provided, the excimer laser being in optical communication with at least one line-narrowing module, wherein the line-narrowing module comprises at least one immersion grating assembly configured to narrow the spectrum of at least one light beam emitted by the excimer laser, then directing the light beam emitted from the laser to at least one optical system configured to condition the emitted light beam, and directing the conditioned light beam to at least one mask or reticle configured to transmit patterned length, and directing the patterned light through at least one projection lens to at least one semiconductor wafer.

Other features and benefits of the embodiments of a method and apparatus for immersion grating photolithography as disclosed will become apparent from a consideration of the following detailed description.

### BRIEF DESCRIPTION OF THE DRAWINGS

The above and further advantages of the embodiments of a method and apparatus for immersion grating photolithography will be explained in more detail by way of the accompanying drawings, wherein:

FIG. 1 shows an echelle grating in a Littrow configuration as known in the prior art;

FIGS. 2A and 2B show schematics of lasers with and without a line-narrowing module wherein a grating is used to narrow the linewidth of the laser, as known in the prior art;

FIGS. 3A and 3B shows a typical graphs of the spectral linewidths of the light emitted by the lasers shown in FIGS. 2A and 2B, as known in the prior art;

FIG. 4 shows an elevated perspective view of an immersion grating as known in the prior art;

FIG. 5 shows a side view an immersion grating with an epoxy adhesive between a grating diffractive surface and a prism surface, as known in the prior art;

FIG. 6 shows a prism wherein a grating structure is replicated onto a surface of the prism, as known in the prior art;

FIG. 7 shows a prism wherein a grating structure is etched or ruled onto a surface of the prism, as known in the prior art;

FIG. 8 shows a graph of simulated grating efficiency relative to wavelength for a grating in air and a grating replicated onto a prism surface;

FIG. 9 shows a schematic of a typical photolithography system for the processing of certain semiconductor structures;

FIG. 10 shows an elevated perspective view of an embodiment of an immersion grating assembly;

FIG. 11 shows an exploded elevated perspective view of the embodiment of the immersion grating assembly shown in FIG. 10;

FIG. 12 shows an exploded side view of the embodiment of an immersion grating assembly shown in FIG. 10;

FIG. 13 shows a side view of an embodiment of the immersion grating assembly shown in FIG. 10 with an immersion medium disposed between the grating diffractive surface and the prism, with a retaining structure located around the grating and the immersion medium;

FIG. 14 shows an embodiment of a UV light source comprising a line narrowing module and an excimer laser where the line narrowing module uses an immersion grating assembly;

FIG. 15 shows a graph of the spectral linewidth of the light emitted by the UV light source shown in FIG. 14;

FIG. 16 shows a graph of simulated grating efficiency relative to wavelength for three cases of immersion gratings with immersion mediums with various indices of refraction; and

FIG. 17 shows a flowchart of a method of UV lithography using a novel immersed echelle grating.

### DETAILED DESCRIPTION

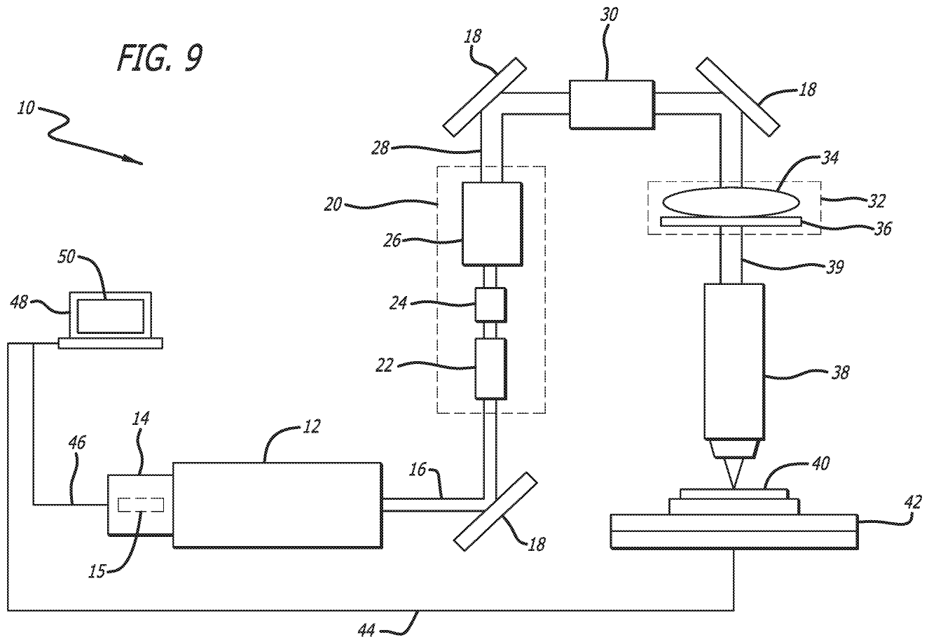

The present application is directed to various embodiments of optical grating assemblies and various light sources that use optical gratings. FIG. 9 shows a schematic of a typical photolithography apparatus 10. As shown, at least one light source 12 may be configured to emits at least one beam 16. Exemplary light sources include, without limitations, excimer lasers, diode lasers, gas lasers, solid state lasers, diode-pumped alkali lasers, optically pumped semiconductor lasers (OPSLs), arc lamps, deep-UV plasma light sources, or extreme-UV plasma light sources and the like. Those skilled in the art will appreciate that any variety of light sources may be used in the photolithography apparatus 10. The light source 12 may be configured to be in optical communication with at least one line-narrowing module 14. The line-narrowing module 14 may comprise one or more gratings 15 that may be used to modify the spectral linewidth of the beam 16. Exemplary gratings include, without limitation, transmissive gratings, reflective gratings, Bragg gratings, holographic gratings, echelle gratings, ruled gratings, replicated gratings, diffraction gratings, blazed gratings and the like. In the illustrated embodiment, the light source 12 may comprise an excimer laser. Typical excimer lasers emit light in a wavelength range between 100 nm and 400 nm. The portion of the UV spectrum between 300 nm and 400 nm is known in the art as the “near-ultraviolet” (NUV). The portion of the UV spectrum between 200 nm and 300 nm is known in the art as the “mid-ultraviolet” (MUV). The portion of the UV spectrum between 100 nm and 200 nm is known in the art as the “deep-ultraviolet” (DUV) or “vacuum ultraviolet” (VUV). Exemplary excimer lasers include, without limitation, ArF (argon fluoride) lasers operating at about 193 nm, KrF (krypton fluoride) lasers operating at about 248 nm and XeF (xenon fluoride) lasers operating at about 351 nm. Excimer lasers operating at about 193 nm and about 248 nm are often used in UV laser lithography. Optionally, Ar₂* excimer lasers operating at about 126 nm or F₂ excimer lasers operating at about 157 nm may be used. Those skilled in the art will appreciate that excimer lasers of many different wavelengths may be used in the UV laser photolithography apparatus 10. Further, those skilled in the art will appreciate that the laser photolithography apparatus 10 may be configured to use any variety of alternate laser systems and/or light sources. The light source 12 and/or the line-narrowing module 14 may be in communication with at least one controller 48 via at least one conduit 46.

As shown in FIG. 9, the apparatus 10 may comprise at least one mirror 18 configured to reflect the beam 16 to at least one optical system 20 that is configured to condition the beam 16. In the illustrated embodiment, the optical system 20 comprises at least one polarizer 22, at least one variable attenuator 24 and at least one beam shaping optical module 26. Optionally, the optical system 20 may comprise a wide variety of optical elements such as wave plates, filters, lenses, gratings and the like. In the illustrated embodiment, the beam 28 exiting the optical system 20 may be spatially wider than beam 16, though those skilled in the art will appreciate that the optical system 20 may change the characteristics of the beam 16 in a number of ways, including collimation, polarization, widening, narrowing, and focusing. The beam 28 may be reflected from another mirror 18 into at least one optical system 30. Optionally, no optical system 30 may be used. As shown, another mirror 18 is configured to direct the beam 28 into at least one optical system 32. In the illustrated embodiment, the optical system 32 includes at least one condenser lens 34 and at least one reticle or mask 36. Optionally, optical system 32 may comprise any number or combination of optical elements. At least one beam 39 exits the optical system 32 and may enter one or more imaging system 38 that is configured to focus and direct the beam 39 to one or more wafers 40. In the illustrated embodiment, the imaging system 38 may comprise one or more refractive or catadioptric imaging lenses. Optionally, the imaging system 38 may use a variety of lenses or optical assemblies. The optical elements of the optical systems 20, 30, 32 and imaging system 38 may have one or more anti-reflective coatings applied to their surfaces. Such anti-reflective coatings may be relatively inefficient for excimer lasers or alternate light sources operating with wide linewidths. Optionally, the optical elements of the optical systems 20, 30, 32 and imaging system 38 may not have anti-reflective coatings. Light from the imaging system 38 may illuminate at least one semiconductor wafer 40 that may be mounted on at least one motion system 42 that is configured to position the wafer 40 in the X, Y, and Z axes. Additionally, the motion system 42 may position the wafer 40 in the tip (pitch), tilt (roll) and theta (yaw) degrees of freedom. Exemplary motion systems 42 are air-bearing stages, servomotor stages, piezo-motion stages, voice-coil stages, flexure stages and the like. Those skilled in the art will appreciate that that the motion system 42 may be configured in any variety of ways. The motion system 42 may be in communication with at least one controller 48 via at least one conduit 44.

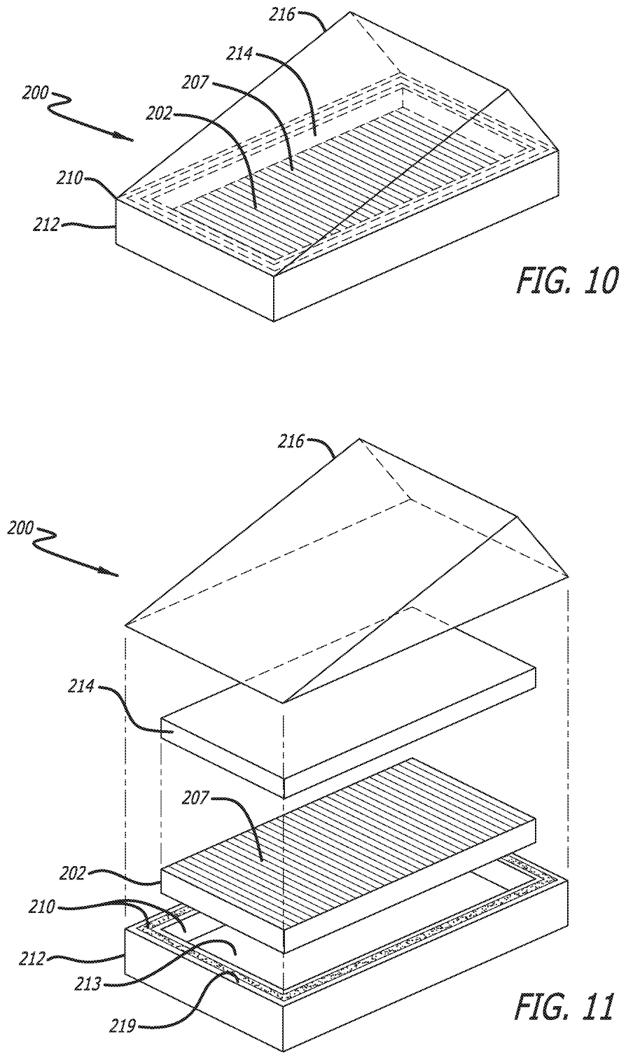

FIGS. 10-14 show various views of an embodiment of an improved immersion grating assembly 200 in accordance with the present disclosure. In the illustrated embodiment, the immersion grating assembly 200 may be configured to be optimized for wavelengths of light shorter than 300 nm. FIGS. 10 and 11 show elevated perspective views of an embodiment of an immersion grating assembly 200. As shown, the immersion grating assembly 200 may comprise at least one grating 202, at least one retaining structure 212, at least one bonding agent 210, at least one immersion medium 214 and at least one prism 216.

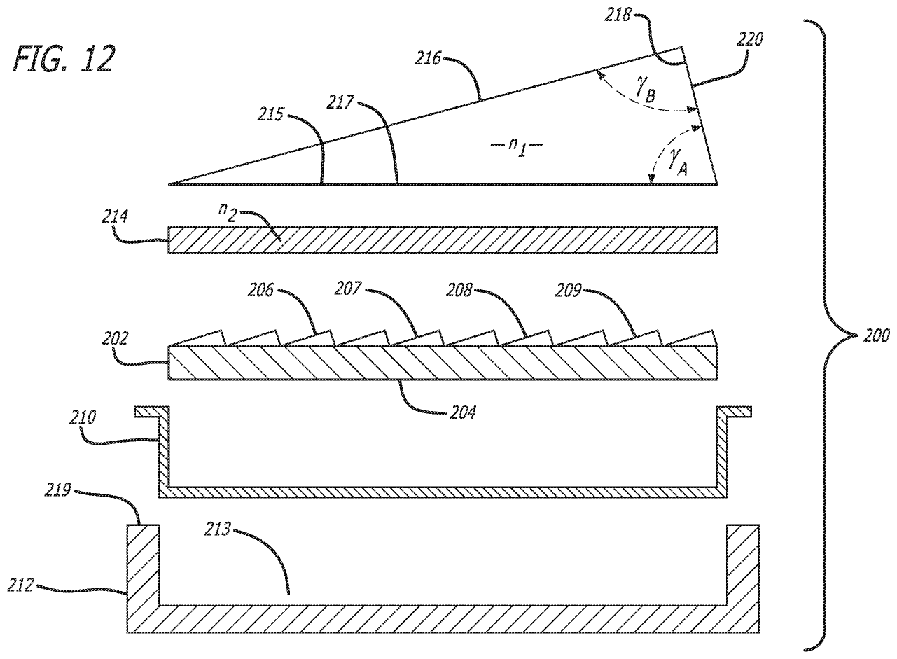

FIG. 12 shows an exploded side view of the embodiment of the immersion grating assembly 200 shown in FIG. 10. In the illustrated embodiment, the grating 202 may comprise at least one substrate 204, at least one grating structure 206 with at least one grating diffractive surface 207 comprising at least one reflective layer 208. In the illustrated embodiment the reflective layer 208 is aluminum. Those skilled in the art will appreciate that any variety of metals or non-metals may be used as the reflective layer 208. In the illustrated embodiment, the grating structure 206 is a replicated echelle structure based on a ruled echelle master grating. Optionally, the grating structure 206 may comprise a holographic structure. Those skilled in the art will appreciate that any variety of grating structures may be used. At least one protective overcoating 209 configured to reduce damage to UV light may be applied to the reflective layer 208 of the grating diffractive surface 207. Exemplary protective overcoatings 209 include, without limitation, alternating layers of various metals, fluorides and oxides, including aluminum, aluminum oxide (Al₂O₃), magnesium fluoride (MgF₂) or silicon dioxide (SiO₂). Those skilled in the art will appreciate that a combination of various metals or dielectrics (fluorides, oxides, etc.) may comprise the protective overcoating 209. Replicated gratings with protective overcoatings are disclosed in U.S. Pat. No. 5,999,220 by Morton, et al., the contents of which are incorporated by reference in their entirety herein. Optionally, the protective overcoating need not be applied to the reflective layer 208 of the grating diffractive surface 207. In the illustrated embodiment, the grating 202 is a replicated echelle grating that is blazed at 193.30 nm. Those skilled in the art will appreciate the grating 202 may be blazed at any variety of wavelengths.

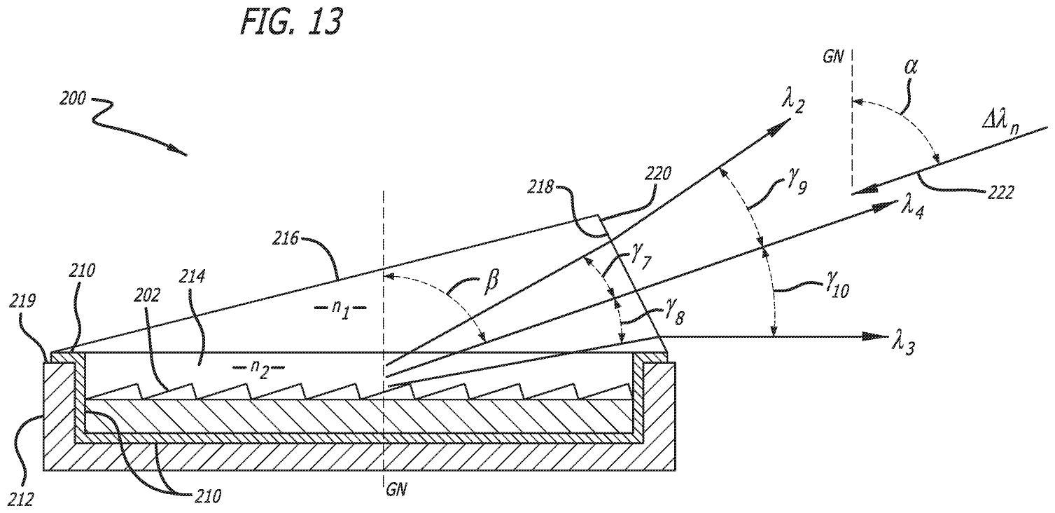

As shown in FIG. 13, the immersion grating assembly 200 may be used in a Littrow configuration, where at least one light beam 222 may be diffracted back in generally parallel to and opposite the direction from where it came. As described above, in a Littrow configuration the angle of incidence α as measured from Grating Normal (GN) is substantially equal to the angle of diffraction β. Optionally, the immersion grating assembly 200 may be used in a near-Littrow or non-Littrow configuration where the angle of incidence α is not substantially equal to the angle of diffraction β.

As shown in FIG. 12, in the illustrated embodiment, the prism 216 may be made of fused silica with a refractive index n₁ between about 1.40 to about 1.55. Those skilled in the art will appreciate that the refractive index of fused silica may not be between 1.40 and 1.55. Optionally, the prism 216 may be made of plastic, glass, quartz, fluorite, calcium fluoride, or BK7. Those skilled in the art will appreciate that the prism 216 may be made from a wide variety of materials with a wide variety of refractive indices. In the illustrated embodiment, the prism 216 may comprise at least one first surface 220 and at least one second surface 215. Anti-reflection coatings 218, 217 configured to maximize the light that may reach the grating diffractive surface 207 may be applied to the surfaces 220, 215, respectively. Optionally, there may be no anti-reflective coatings applied to surfaces 220, 215. In the illustrated embodiment, the prism 216 is a fused silica right angle prism with a refractive index of n₁ of 1.50, a first prism angle γ_{A}=80° and a second prism angle γ_{B}=90°. The first prism angle γ_{A} is selected so that the Littrow condition for the grating 202 is satisfied with incident light at normal incidence to the surface of the prism 216. Those skilled in the art will appreciate that other prism configurations may be used and that the prism 216 may not be a right angle prism, and that the prism 216 may be selected such that incident light is not directed normal to the surface 220.

As shown in FIGS. 12 and 13, an immersion medium 214 with a refractive index n₂ may be applied between the second surface 215 of prism 216 and the grating diffractive surface 207. Exemplary immersion media 214 may include non-adhesives such as gels, mineral spirits, glycerol, water, glycerol-water mixtures and the like. The immersion medium 214 may be configured to stay viscous in the presence of UV radiation. Optionally, the gain medium may become solid in the presence of UV radiation. Those skilled in the art will appreciate that the viscosity of the immersion medium 214 may change or not change in the presence of UV radiation. Optionally, the immersion medium 214 may be a gas or a non-Newtonian fluid. The immersion medium 214 may also comprise various adhesives such as epoxies, RTV silicones, acrylics, cyanoacrylates, urethanes, polyurethanes, UV-curable adhesives, thermal-curable adhesives, optical adhesives and the like, though some adhesives may deleteriously affect the efficiency of the immersion grating assembly 200 as described above. Those skilled in the art will appreciate that any variety of adhesive or non-adhesive materials may be used as the immersion medium 214. In the illustrated embodiment, the immersion medium 214 may have a refractive index n₂ substantially identical to that of the prism 216. Those skilled in the art will appreciate that the index of refraction n₂ of the immersion medium 214 may not be substantially identical to that of the prism 216. Without the immersion medium 214, an incident light beam 222 may encounter a prism-air interface between the second surface 215 of the prism 216 and the grating diffractive surface 207 such that total internal reflection of the light beam 222 may change its direction of propagation, potentially at the exclusion of it properly reaching the grating diffractive surface 207.

As discussed above, absorption of UV light by the immersion medium 214 may reduce the efficiency of the immersion grating assembly 200. To avoid this, the immersion medium 214 may be selected to be highly transmissive to UV light. Optionally, the immersion medium 214 may not be highly transmissive to UV light, but be more transmissive to UV light than prior art immersion mediums. In the illustrated embodiment, the immersion medium 214 may comprise a glycerol-water mixture configured to have low absorption of UV light at 193.30 nm and to have an index of refraction n₂ that substantially matches the index of refraction n₁ of the prism 216. Those skilled in the art will appreciate that the immersion medium 214 may have low absorption at wavelengths of UV light other than 193.30 nm. In the illustrated embodiment, because the immersion medium 214 may not be an adhesive, at least one retaining structure 212 along with at least one bonding agent 210 (as described above) may be required to hold the grating 202, prism 216, and the immersion medium 214 together and prevent the absorption of contamination and moisture by the immersion medium 214. As shown in FIG. 11, the retaining structure 212 may comprise at least one internal volume 213 configured to receive the grating 202, the immersion medium 214 and the bonding agent 210. The retaining structure 212 may also comprise at least one circumferential surface 219.

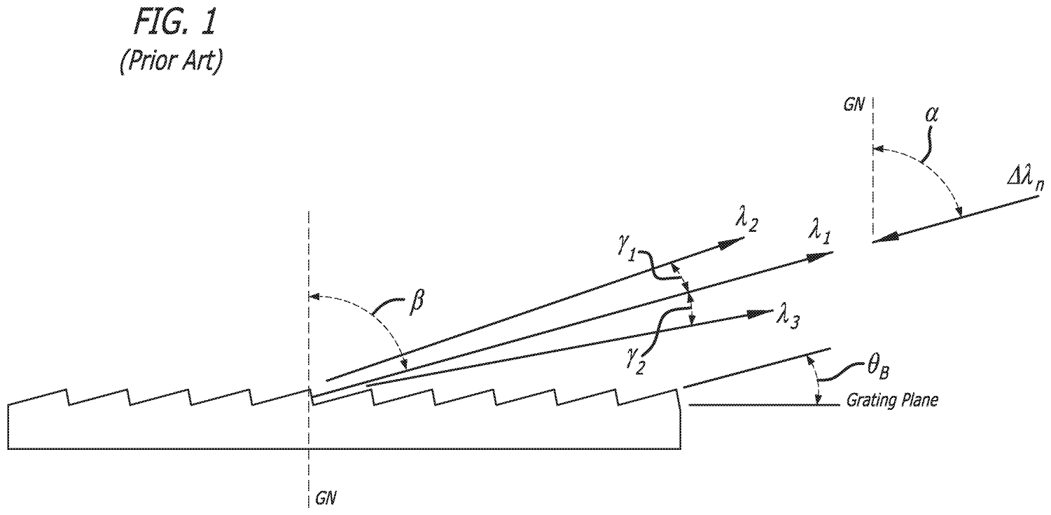

The present application also discloses a method of manufacture of an immersion grating assembly 200 described herein. With reference to FIGS. 10 through 13, the first step in making the immersion grating assembly 200 is to select the grating to be immersed. In the illustrated embodiment, the grating 202 selected is an echelle grating configured with relatively low groove density with a groove shape optimized for high incidence angles α and high diffraction angles β and used in high diffraction orders as described above with respect to FIGS. 1 and 13. Those skilled in the art will appreciate that a wide variety of gratings may be used selected for a wide variety of incidence angles and diffraction angles. The prism 216 may be designed or selected to have high transmission in the spectral range the immersion grating assembly 200 will be used in, though those skilled in the art will appreciate that the prism 216 may not be highly transmissive in that spectral range. In the illustrated embodiment, the prism 216 is fabricated from fused silica. Alternative prism materials are described above.

In the illustrated embodiment, the bonding agent 210 may be applied in the retaining volume 213 and the grating 202 may be placed in the retaining volume 213 and retained therein. In the illustrated embodiment, the bonding agent may comprise an epoxy polymer. Optionally, any variety of adhesives, such as RTV silicones, acrylics, cyanoacrylates, urethanes, polyurethanes, UV-curable adhesives, thermal-curable adhesives, optical adhesives and the like may be used. After the grating 202 is bonded to, coupled to, or otherwise retained on or within the retaining structure 212, at least one immersion medium 214 may be applied over the grating surface 207. Though the immersion medium 214 is depicted as a rectangular prism in FIGS. 11 and 12, in the illustrated embodiment the immersion medium 214 may be a fluid or gel that may be dispensed in between the grating diffractive surface 207 and the second prism surface 215. Optionally, the immersion medium 214 may comprise a viscous pre-form that is laid into the volume between the grating diffractive surface 207 and the second prism surface 215. Those skilled in the art will appreciate that the immersion medium 214 may be placed in contact with the prism surface 215 and the grating diffractive surface 207 in a variety of ways. The bonding agent 210 may also be applied to the circumferential surface 219, enabling the circumference of the prism surface 215 to be bonded to the retaining structure 212. Those skilled in the art will appreciate that a wide variety of assembly methods may be employed in the manufacture of the immersion grating assembly 200.

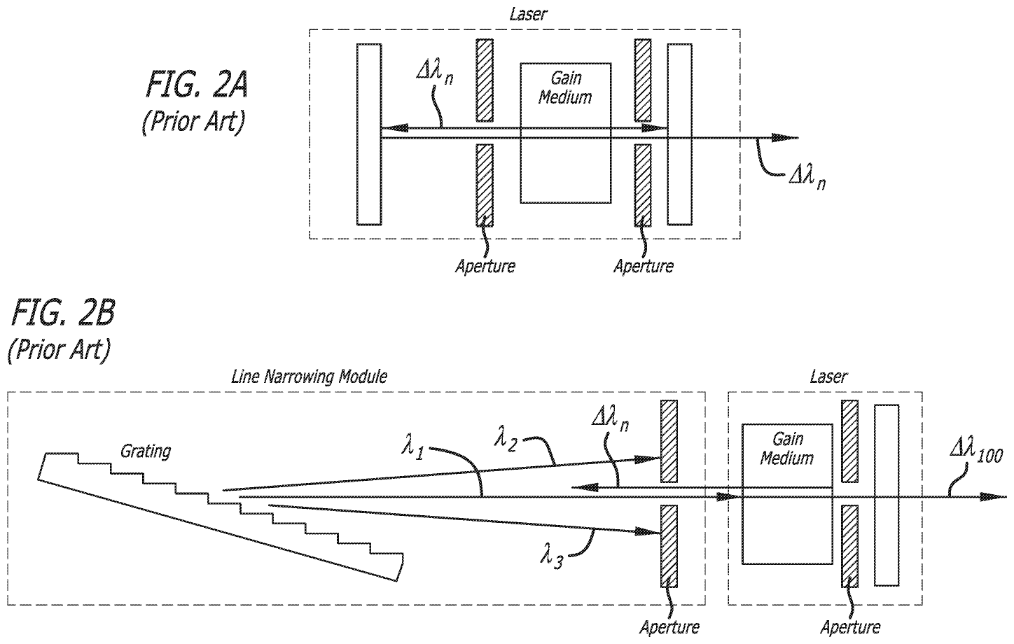

Referring to FIG. 13, during use, at least one light beam 222 with a spectral linewidth Δλₙ centered at wavelength λ₄ may be directed to the immersion grating assembly 200 at angle of incidence α relative to GN. In the illustrated embodiment, the center wavelength λ₄ is 193.30 nm. Those skilled in the art will appreciate that the center wavelength λ₄ may be any wavelength. In the illustrated embodiment, the grating 202 is configured in Littrow or near-Littrow so that the center wavelength λ₄ may be reflected or diffracted at diffraction angle β relative to GN, such that the diffraction angle β is substantially equal to incidence angle α. As such, the portion of the beam 222 with wavelength 193.30 nm may be diffracted or reflected back in a substantially opposite and parallel direction that the beam 222 came from. Light beams with wavelengths λ₂ and λ₃ may be diffracted by the grating 202 at angles γ₇ and γ₈ respectively. Those skilled in the art will appreciate that light with other wavelengths may also be diffracted at any variety of angles relative to the incidence angle α of the incident light beam 222. The light beams with wavelengths λ₂ and λ₃ may also be refracted per Snell's law as they exit the prism 216, bringing the total angular dispersion of the light beams with wavelengths λ₂ and λ₃ to angles γ₉ and γ₁₀ respectively relative to the incidence angle α of the incident light beam 222. In the illustrated embodiment, the dispersion capability of the immersion grating assembly 200 is such that the angles γ₉ and γ₁₀ are greater than the angles γ₁ and γ₂ of the prior art grating 100 shown in FIG. 2 as shown in Equation 1 below.

γ₉>γ₁;γ₁₀>γ₂ (Eq. 1)

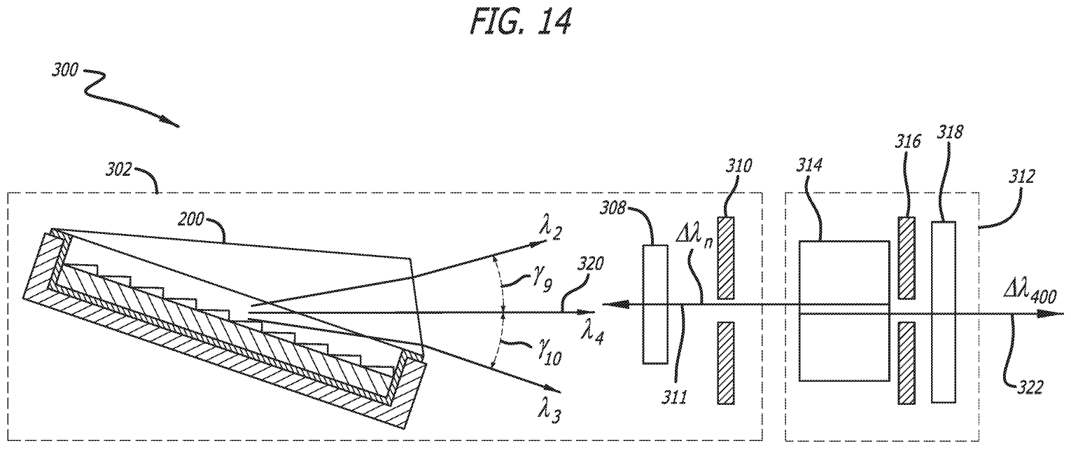

An improved light source 300 in accordance with the present disclosure is shown in FIG. 14. As shown, the light source 300 may comprise at least one excimer laser 312 in optical communication with at least one line narrowing module 302. As shown, the excimer laser 312 may comprise at least one laser gain medium 314 in optical communication with at least one output aperture 316 and at least one output optic 318. The line narrowing module 302 may comprise at least one immersion grating assembly 200 (described above) configured to be in optical communication with at least one optical system 308 and at least one aperture 310. In the illustrated embodiment, the aperture 310 is located in the line narrowing module 302 between the excimer laser 312 and the optical system 308. Optionally, the aperture 310 may be located proximal to the immersion grating assembly 200 or in any other location in the line narrowing module 302. Also, the aperture 310 may be located in the excimer laser 312. Those skilled in the art will appreciate that there may be no optical system 308 or aperture 310 positioned anywhere between the gain medium 314 and the immersion grating assembly 200. The optical system 308 may comprise prisms, mirrors, lenses, waveplates, and the like to direct light between the excimer laser 312 and the immersion grating assembly 200. Those skilled in the art will appreciate that any variety of optical elements may be used in the optical system 308.

During use, at least one light beam 311 with at least one spectral linewidth Δλₙ centered at wavelength λ₄ may be directed from the excimer gain medium 314 through the aperture 310 and the optical system 308 in the line narrowing module 302 to the immersion grating assembly 200. A light beam 320 with a wavelength λ₄ may be reflected or diffracted by the immersion grating assembly 200 back in a substantially opposite and parallel direction from which the beam 311 came. The light from the beam 311 at wavelengths λ₂ and λ₃ may be dispersed by the immersion grating assembly 200 at angles γ₉ and γ₁₀ respectively. The light with wavelength λ₄ may be diffracted or reflected back through the aperture 310 and into the excimer gain medium 314 where it is amplified and exits the excimer laser as light beam 322 with a spectral linewidth Δλ₄₀₀. Due to the angular dispersion imparted on the light beam 311 by the immersion grating assembly 200, the light beams with wavelengths λ₂ and λ₃ from the beam 311 may be blocked by the aperture 310 from reaching the gain medium 314 and thus may not be amplified in the excimer laser gain medium 314. Optionally, the light beams with wavelengths λ₂ and λ₃ may not be blocked by the aperture 310, but instead enter the gain medium 214 and, due to their angular dispersion, may couple into non-resonant modes in the laser cavity and are thus not amplified and emitted by the light source 300 as part of the output light beam 322.

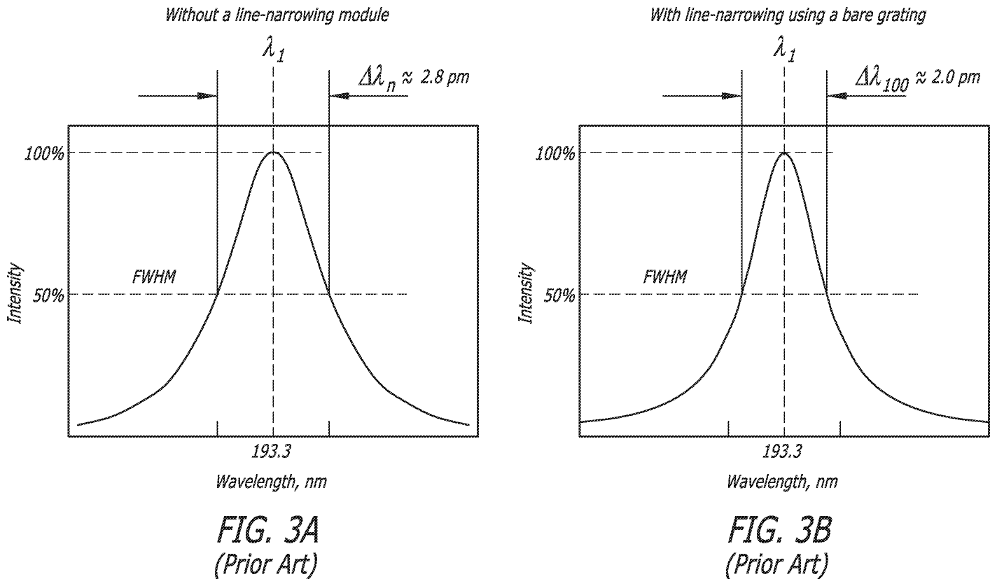

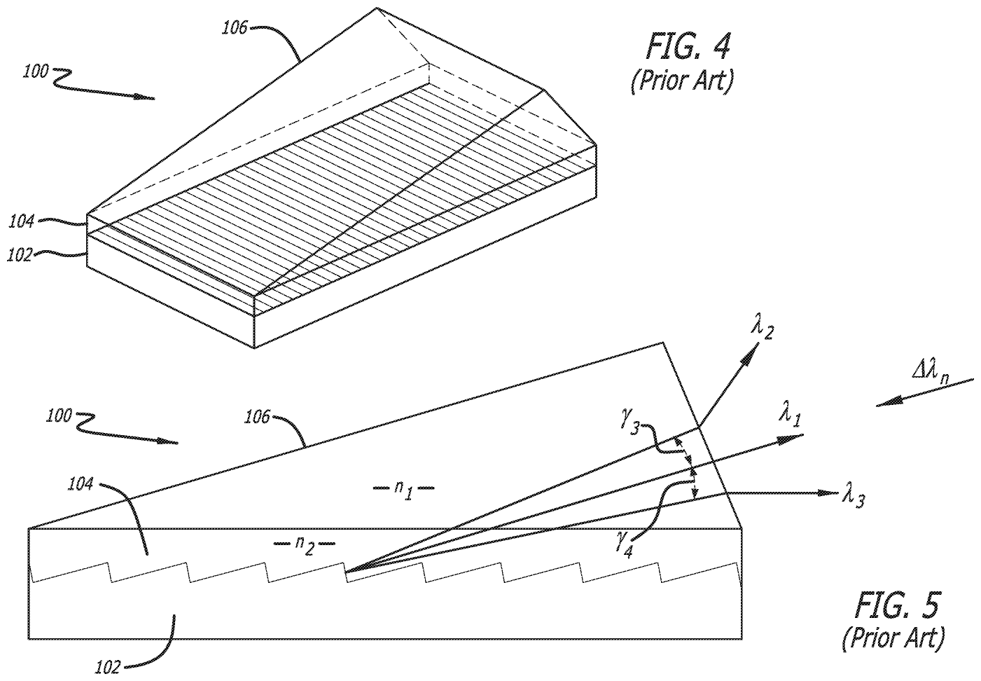

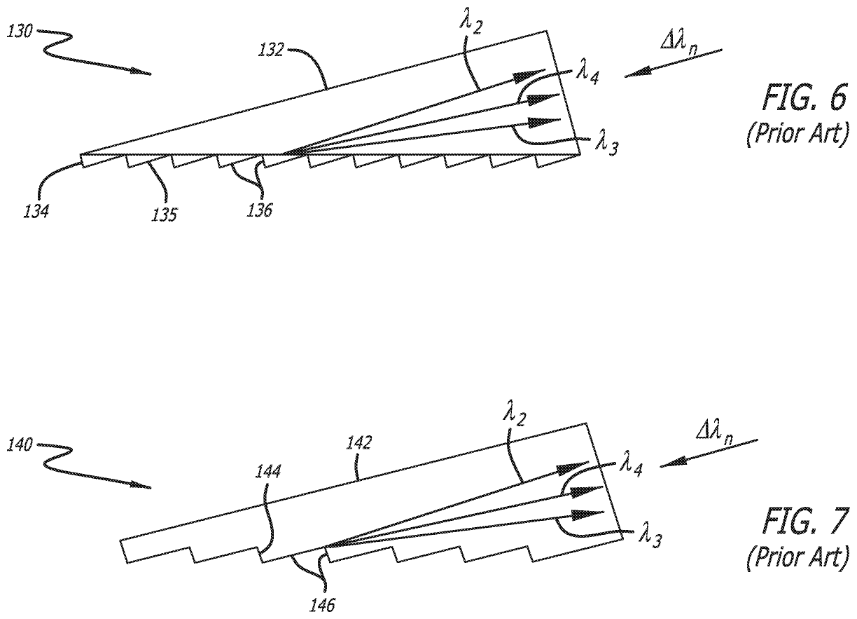

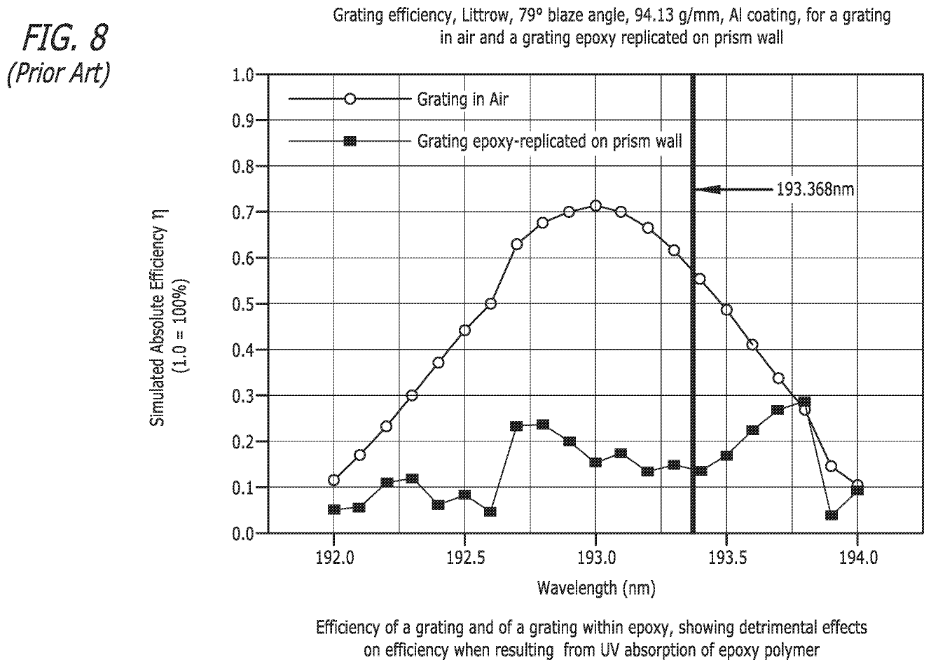

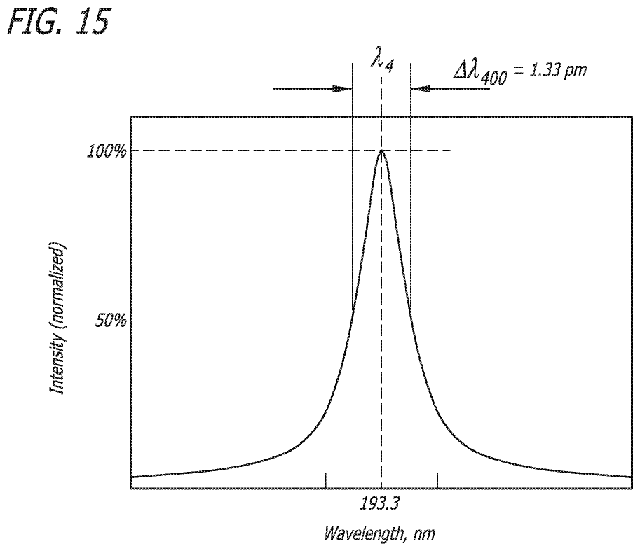

As described above, the output light beam 322 has a spectral linewidth Δλ₄₀₀ that is narrower than the output light beam emitted by the prior art light source that uses a prior art bare grating that has spectral linewidth Δλ₁₀₀ as described above with respect to FIGS. 2B and 3B. FIG. 15 shows a graph of the spectral linewidth of the light beam 322 emitted by the light source 300 shown in FIG. 14. Because the light dispersed by an immersed grating generally has a spectral linewidth that is narrower by the inverse of the refractive index n₂ of the immersion medium (relative to n=1 in air), the resulting narrowed linewidth Δλ₄₀₀ satisfies Equation 2 below. In the illustrated embodiment, the refractive index n₂ of the immersion medium is 1.5 and the spectral linewidth Δλ₁₀₀ of the prior art excimer laser with a line-narrowing module using a bare grating (shown in FIG. 3) is 2.0 pm, so Equation 2 yields a spectral linewidth Δλ₄₀₀=1.33 pm.

$${Δλ}_{400} = \frac{{Δλ}_{100}}{{n}_{2}} = \frac{2.0 pm}{1.5} = 1.33 pm$$

Those skilled in the art will appreciate that the result detailed in Equation 2 is meant only as an illustration of a specific embodiment of an improved light source 300 with an immersion grating assembly with specific parameters. For example, the spectral linewidth Δλₙ may be greater than or less than 2.8 pm, and spectral linewidth Δλ₁₀₀ may be greater than or less than 2.0 pm. Other results depend on a variety of factors, including but not limited to, the grating configuration, the immersion medium used, the prism used, the angle of incidence of the incoming beam, the blaze wavelength, whether the grating is in a Littrow configuration, and a variety of other factors appreciated by those skilled in the art.

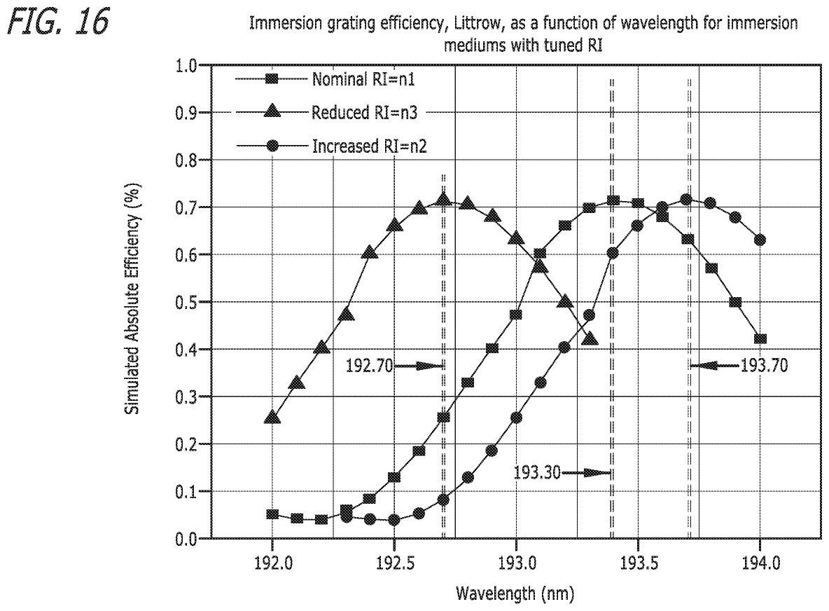

A significant advantage of the immersion grating assembly 200 is the modularity of design parameters. For example, a variety of combinations of prisms and immersion mediums may be used to achieve a wide variety of dispersion properties as needed to suit a particular application or system. Also, the index of refraction n₂ of the immersion medium 214 may be adjusted or “index-tuned” by a variety of methods. Some immersion mediums lend themselves to index tuning while others do not. For example, the index of refraction of the glycerol-water mixture used as the immersion medium 214 may be selected, configured or otherwise tuned by varying the relative masses of the constituent components such as the ratio of glycerol to water. For example, by tuning the index of refraction of the immersion medium 214, the blaze wavelength of the immersion grating assembly 200 may be tuned to shift the peak of the efficiency curve as needed by a particular requirement. FIG. 16 shows a graph of grating efficiency relative to wavelength for an immersion grating with immersion mediums with alternative refractive indices (RI). As such, the wavelength at which the immersion grating operates at peak efficiency may be selected by varying the composition of the immersion medium. For example, as shown in FIG. 16, using an immersion medium of a nominal index n₁ may enable a peak efficiency at about 193.30 nm. Alternatively, the use of an immersion medium with higher index n₂ may shift the efficiency curve to the right, moving the wavelength of peak efficiency to about 193.70 nm. Using an immersion medium of a reduced index n₃ may shift the peak efficiency to a shorter wavelength of about 192.70 nm. Those skilled in the art will appreciate that a wide variety of formulations of the immersion mediums may be used to achieve peak efficiencies for any variety of wavelengths.

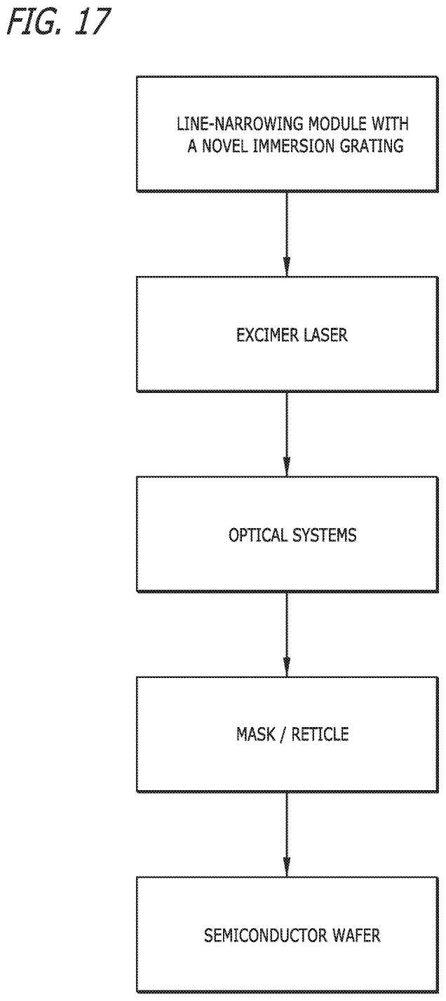

FIG. 17 shows a simplified schematic of a process of excimer laser lithography. In the illustrated embodiment, at least one excimer laser is provided that is in optical communication with at least one line narrowing module, wherein the line narrowing module comprises at least one immersion grating configured to narrow the spectrum of at least one light beam emitted by the excimer laser. At least one optical component directs the beam emitted by the excimer laser to at least one optical system configured to condition the light beam and direct the conditioned light beam to at least one mask or reticle, the mask or reticle being configured to provide patterned light and transmit the patterned light through at least one projection lens to at least one semiconductor wafer. At least one motion control system is configured to adjust the position of the semiconductor wafer in one or more axes, including X, Y, Z and tip, tilt and theta. The excimer laser and motion control system are in communication with at least one control system via at least one conduit, the control system being configured to control the output of the excimer laser and the position of the semiconductor wafer with one or more control signals.

The embodiments disclosed herein are illustrative of the principles of the invention. Other modifications may be deployed which are within the scope of the invention. Accordingly, the devices disclosed are not limited to those precisely shown and described herein.

What is claimed is:

1. An immersion grating assembly, comprising:
at least one optical grating including at least one grating structure and at least one grating diffractive surface, the at least one optical grating configured to be positioned in a Littrow or near-Littrow configuration and provide optical dispersion for ultraviolet light;
at least one prism formed from at least one UV-transmitting material with at least a first index of refraction, the at least one prism having a first prism surface and at least one second prism surface;
at least one immersion medium with at least a second index of refraction, the at least one immersion medium disposed between the at least one second prism surface and the at least one grating diffractive surface, wherein the first index of refraction of the at least one prism and the at least one second index of refraction of the at least one immersion medium are substantially equal and wherein the at least one immersion medium is substantially transmissive at wavelengths less than about 300 nanometers;
at least one retaining structure configured to confine and retain the at least one optical grating and the at least one immersion medium and prevent the at least one immersion medium from absorbing contamination and moisture; and
at least one bonding agent configured to bond the at least one prism to at least one surface of the at least one retaining structure.

2. The immersion grating assembly of claim 1, wherein the at least one immersion medium is substantially transmissive at wavelengths between about 100 nanometers and about 450 nanometers.

3. The immersion grating assembly of claim 1, wherein the at least one immersion medium is substantially transmissive at wavelengths between about 300 nanometers and about 400 nanometers.

4. The immersion grating assembly of claim 1, wherein the at least one immersion medium is substantially transmissive at wavelengths below about 250 nanometers.

5. The immersion grating assembly of claim 1, wherein the at least one immersion medium is substantially transmissive at wavelengths below about 200 nanometers.

6. The immersion grating assembly of claim 1, wherein the at least one immersion medium is substantially transmissive at wavelengths below about 150 nanometers.

7. The immersion grating assembly of claim 1, wherein the at least one immersion medium is a fluid.

8. The immersion grating assembly of claim 6, wherein the at least one immersion medium is a glycerol-water mixture.

9. The immersion grating assembly of claim 1, wherein the at least one immersion medium is an adhesive.

10. The immersion grating assembly of claim 1, wherein the at least one immersion medium is a viscous pre-form.

11. The immersion grating assembly of claim 1, wherein the index of refraction of the at least one immersion medium is higher than the index of refraction of the at least one prism.

12. The immersion grating assembly of claim 1, wherein the index of refraction of the at least one immersion medium is lower than the index of refraction of the at least one prism.

13. An immersion grating assembly, comprising:
at least one optical grating including at least one grating structure and at least one grating diffractive surface, the at least one optical grating configured to be positioned in a Littrow or near-Littrow configuration and provide optical dispersion;
at least one prism formed from at least one optically transmitting material with at least a first index of refraction, the at least one prism having a first prism surface and at least one second prism surface;
at least one immersion medium with at least a second index of refraction, the at least one immersion medium disposed between the at least one second prism surface and the at least one grating diffractive surface, wherein the first index of refraction of the at least one prism and the at least one second index of refraction of the at least one immersion medium are substantially equal and wherein the at least one immersion medium is substantially transmissive at wavelengths between about 300 nanometers and about 800 nanometers;
at least one retaining structure configured to confine and retain the at least one optical grating and the at least one immersion medium and prevent the at least one immersion medium from absorbing contamination and moisture; and
at least one bonding agent configured to bond the at least one prism to at least one surface of the at least one retaining structure.

14. The immersion grating assembly of claim 13, wherein the at least one immersion medium is substantially transmissive at wavelengths between about 300 nanometers and about 450 nanometers.

15. The immersion grating assembly of claim 13, wherein the at least one immersion medium is substantially transmissive at wavelengths between about 450 nanometers and about 600 nanometers.

16. The immersion grating assembly of claim 13, wherein the at least one immersion medium is substantially transmissive at wavelengths below about 600 nanometers and about 780 nanometers.

17. The immersion grating assembly of claim 13, wherein the at least one immersion medium is a fluid.

18. The immersion grating assembly of claim 17 wherein the at least one fluid is a glycerol-water mixture.

19. The immersion grating assembly of claim 13, wherein the at least one immersion medium is an adhesive.

20. The immersion grating assembly of claim 13, wherein the at least one immersion medium is a viscous pre-form.

21. The immersion grating assembly of claim 13, wherein the index of refraction of the at least one immersion medium is higher than the index of refraction of the at least one prism.

22. The immersion grating assembly of claim 13, wherein the index of refraction of the at least one immersion medium is lower than the index of refraction of the at least one prism.

23. A method of manufacturing an immersion grating assembly, comprising:
selecting at least one optical grating having at least one grating structure and at least one grating diffractive surface, the at least one optical grating configured to be positioned in a Littrow or a near-Littrow configuration and to provide optical dispersion for ultraviolet light;
selecting at least one prism formed from at least one UV-transmissive material with at least a first index of refraction, the at least one prism having a first prism surface and at least one second prism surface, the at least one prism having at least a first index of refraction;
optically contacting the at least one grating diffractive surface to the at least one second surface of the prism using at least one immersion medium with at least a second index of refraction, such that reflections between the at least one second surface of the prism and the at least one grating diffractive surface are minimized;
installing the at least one optical grating and the at least one immersion medium within at least one retaining structure, the at least one retaining structure configured to prevent the at least one immersion medium from absorbing contamination and moisture; and
bonding the at least one prism to at least one surface of the at least one retaining structure with at least one bonding agent.

24. The method of claim 23, further comprising tuning the wavelength of peak dispersion efficiency of the at least one grating assembly by selectively changing the index of refraction of the at least one immersion medium.

25. A method of line-narrowing an excimer laser, comprising;
supplying at least one immersion grating assembly in optical communication with at least one excimer laser gain medium, wherein the at least one immersion grating assembly is configured to provide angular dispersion to at least one first light beam having at least a first central wavelength and at least a first spectral linewidth;
directing the at least one first light beam from the at least one excimer laser gain medium to the at least one immersion grating assembly;
diffracting the at least one first light beam with the at least one immersion grating assembly such that at least a second light beam with at least one second central wavelength is reflected back in substantially the opposite direction to, and substantially parallel to, the direction the at least one first light beam came from;
providing at least one aperture configured to allow only the at least one second light beam to propagate back into the at least one excimer laser gain medium; and
amplifying the at least one second light beam in the at least one excimer laser gain medium and outputting at least one emitted light beam with at least a second spectral bandwidth centered around the at least one second central wavelength of the at least one second light beam, wherein the at least one second spectral linewidth of the at least one emitted light beam is less than the at least one first spectral linewidth of the at least one first light beam.

26. A method of excimer laser lithography:
providing at least one excimer laser, at least one the excimer laser in optical communication with at least one line narrowing module, wherein the line narrowing module comprises at least one immersion grating assembly configured to narrow the spectrum of at least one light beam emitted by the at least one excimer laser;
directing the at least one light beam emitted by the at least one excimer laser to at least one optical system configured to condition the light beam;
directing the conditioned light beam to at least one mask or reticle, the at least one mask or reticle being configured to provide patterned light; and
directing the patterned light through at least one projection lens to at least one semiconductor wafer.
